(19) United States
(12) Patent Application Publication
(10) Pub. No.: US 2007/0089023 A1
(43) Pub. Date: Apr. 19, 2007

(54) System and method for system resource access

(75) Inventor: Richard Sanders, Hutto, TX (US)

Correspondence Address: TOLER SCHAFFER, LLP, 8500 BLUFFSTONE COVE, SUITE A201, AUSTIN, TX, 78759, US

(73) Assignee: SigmaTel, Inc., Austin, TX (US)

(21) Appl. No.: 11/241,682

(22) Filed: Sep. 30, 2005

(51) Int. Cl. H03M 13/00

(52) U.S. Cl. 714/758

(57) ABSTRACT

The disclosure is directed to a controller including a memory interface to a memory device, a device driver configured to access the memory device via the memory interface, and a resource loader to provide a memory location of a resource to the device driver. The device driver is configured to access the memory location on the memory device and to retrieve the resource and an error correction code associated with the resource. Error correction is performed on the resource based on the associated error correction code.

### FIELD OF THE DISCLOSURE

This disclosure, in general, relates to systems and methods for system resource access.

### BACKGROUND

Consumer electronic devices, such as cellular telephones, digital music players, thumb drives and other handheld devices, execute increasingly complicated algorithms, such as algorithms for decoding compressed digital audio and video data and user interface algorithms. As the complexity of these algorithms increases, so does the memory usage for storing such algorithms.

Increasingly, manufacturers are turning to solid-state memory devices, such as flash memory devices including NAND flash and NOR flash memory devices. Typically, solid-state memory devices store data in logical units, such as memory pages and memory blocks. A set of memory pages form a memory block. Often, data is written to a page and may be read from locations within that page. Typically, a block is the smallest amount of data that may be erased. In a typical flash device, each page has a data area and an overhead area or metadata area, sometimes referred to as a redundant data area. The overhead or metadata area of the page stores information about the page, about data within the page, and about the organization of the page.

Increasingly, manufacturers are storing system resources on solid-state flash memory devices. Such solid-state flash memory devices provide certain performance improvements over hard drives. However, flash memory devices are generally slower than read only memory (ROM) devices and other memory devices more closely associated with processors. On the other hand, read-only memory (ROM) devices are expensive and are poorly suited for storing large algorithms and system resources.

As such, an improved system and method for storing and accessing system resources would be desirable.

### BRIEF DESCRIPTION OF THE DRAWINGS

FIGS. 1 and 2 include illustrations of components found in exemplary electronic devices.

FIGS. 3, 4 and 5 include illustrations of exemplary data organization in a memory device.

FIGS. 6 and 7 include illustrations of exemplary methods for storing and accessing system resources.

### DESCRIPTION OF THE DRAWINGS

In a particular embodiment, the disclosure is directed to an electronic device including a memory controller and a memory device accessible by the memory controller. The memory device is organized into pages, each page including a data area and an overhead or metadata area. Typically, the metadata area includes an error correction code associated with the page as a whole. In an exemplary embodiment, the memory device is configured to store a system resource and an error correction code associated with the system resource in the data area of a page. When accessing the system resource, the controller may access the system resource and the associated error correction code (ECC) and perform error correction on the system resource using the associated ECC. In a particular embodiment, the controller accesses the system resource and the error correction code (ECC) associated with the system resource without reading the whole page on which the system resource is stored and without performing error correction of the whole page. When configuring the device, the manufacturer may form a system resource image that includes an error correction code (ECC) associated with each system resource. This image may be loaded into the data areas of pages within the memory device.

In another particular embodiment, the disclosure is directed to a controller including a memory interface to a memory device, a device driver configured to access the memory device via the memory interface, and a resource loader to provide a memory location of a resource to the device driver. The device driver is configured to access the memory location on the memory device and to retrieve the resource and an error correction code associated with the resource. Error correction is performed on the resource based on the associated error correction code.

In another exemplary embodiment, the disclosure is directed to a method of providing system resources for an electronic device. The method includes providing a set of system resources, determining an error correction code for a system resource of the set of system resources, and storing the error correction code and the system resource in a system resource image.

In a further exemplary embodiment, the disclosure is directed to a method of accessing a system resource. The method includes determining a memory location and a size of the system resource, retrieving the system resource and an error correction code associated with the system resource from a memory device based on the location and size of the system resource, and performing error correction on the system resource based on the error correction code.

The disclosure is also directed to a memory device including a memory page including first system resource data and first error correction code data. The first error correction data is associated with the first system resource data. The memory device also includes metadata associated with the memory page. The metadata includes second error correction data associated with the memory page.

In addition, the disclosure is directed to an electronic device including a memory device and a controller. The memory device includes a memory page including first system resource data and first error correction code data. The first error correction data is associated with the first system resource data. The memory device also includes metadata associated with the memory page. The metadata includes second error correction data associated with the memory page. The controller includes a device driver configured to access the memory device and includes a resource loader configured to provide a memory location of the first system resource data to the device driver. The device driver is configured to access the memory device at the memory location and to retrieve the first system resource data and the first error correction data. The controller is configured to perform error correction on the first system resource data based on the first error correction data.

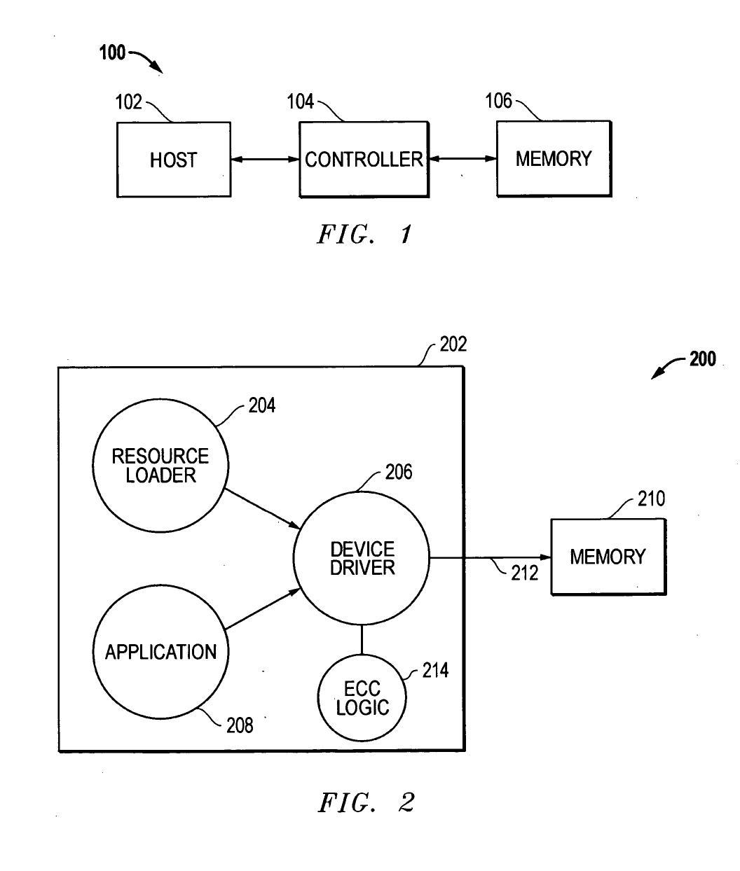

FIG. 1 includes an illustration of an exemplary system 100 including a controller 104 coupled to a memory device 106. Optionally, the controller 104 may be coupled to a host 102. For example, the controller 104 may be accessible by the host 102 via a data bus. In an exemplary embodiment, the host 102, the controller 104 and the memory device 106 are co-located as elements in a single electronic device. In another exemplary embodiment, the controller 104 and the memory device 106 are located in a separate electronic device from the host 102. For example, the host 102 may access the controller 104 via a serial data interface, such as a universal serial bus (USB) interface.

Typically, the host 102 accesses system resources and data stored on the memory device 106 by requesting the resource or data from the controller 104. System resources include firmware, such as system functions, user interface components, and compression algorithms. Exemplary user interface components include fonts, images, and other display data useful in forming a user interface, such as a graphical user interface. Decompression algorithms include, for example, audio and image compression and decompression algorithms. In one exemplary embodiment, an audio player may include decompression algorithms for compressed audio files, such as Windows Media Audio (WMA), Movie Picture Experts Group (MPEG)-1 audio layer 3 (MP3), Advanced Audio Coding (AAC), MPEG, and Ogg Vodis (OGG) files. In addition, the memory device 106 may store data, such as compressed audio files, user data, and other user accessible or manipulated data files.

In one exemplary embodiment, the memory device 106 is a solid-state memory, such as a flash memory device. In a particular embodiment, the memory device 106 is a NAND flash memory device. Typically, the memory device 106 is organized into a set of memory blocks, each memory block including a set of memory pages. The memory pages include a data area and an overhead or metadata area. For example, a memory page may include 528 bytes of memory. The data area of the memory page may be 512 bytes and the overhead or metadata area may be 16 bytes. Often, an error correction code (ECC) is associated with each memory page and stored in the overhead or metadata area of the page. Typically, ECC detection and correction algorithms are configured for a particular data size, for example, 512 bytes. For pages having data areas larger than 528 bytes, a set of ECCs may be stored in the metadata area of the page. Each ECC of the set of ECCs may be associated with a 512 byte portion of the page.

In a particular embodiment, the electronic device 100 includes system resources stored within pages of the memory device 106. Individual system resources are associated with an error correction code (ECC) that is stored in the data area of the pages with the associated system resource. For example, the memory device 106 may include a page including both an ECC in the metadata area associated with the page as a whole and an ECC associated with a system resource and stored in the user accessible data area. The controller 104 is configured to access the individual system resources by accessing the location of the system resource within a page and reading the system resource and the associated error correction code (ECC). In one exemplary embodiment, the controller 104 accesses a system resource stored on the memory device 106, reading the system resource and the associated error correction code (ECC) without reading the entire page in which the system resource is stored. The controller 104 may perform error detection and correction on the system resource based on the associated ECC and without performing error detection and correction on the page as a whole.

When accessing user data, the controller 104 may use traditional memory access methods. For example, the controller 104 may access the memory device 106 to retrieve an entire page including requested user data and perform error detection and correction using an ECC stored in the overhead area of the page including the requested data. When writing data to the memory device 106, the controller 104 may write a page and determine an error correction code for storage in the overhead area of the page. Typically, system resources are loaded as a system image when manufactured or during firmware updates and are not written during device use.

In a particular embodiment, the host and controller form a processing system implemented using a combination of hardware and software. For example, the host and controller may be configured as a system-on-a-chip. In one exemplary embodiment, a processing system 202 includes a system resource loader 204 and a device driver 206, as illustrated by the electronic device 200 of FIG. 2. For example, in response to a request for a system resource, the resource loader 204 directs the device driver 206 to access the memory device 210 via an interface 212. In one embodiment, the resource loader 204 provides a sector offset, resource offset, and resource length of a requested resource. The device driver 206 accesses the resource at the location indicated by the resource loader 204 and retrieves the resource and its associated ECC from the memory device 210. In a particular embodiment, the resource loader 204 accesses a table or set of pointers directing or indicating the location of individual system resources. For example, a table indicating the location of a resource may be stored on the memory device 210 or in the processing system 202.

Upon retrieving the system resource and the associated ECC, the device driver 206 performs error detection and correction on the system resource using the associated ECC. In one exemplary embodiment, the processing system 202 includes a software version of an ECC algorithm 214 for error detection and correction. In another exemplary embodiment, the processing system 202 includes a hardware version of ECC error detection and correction algorithms 214. In a further exemplary embodiment, the processing system 202 includes a combination of software and hardware implementations of error correction code (ECC) algorithms 214. Alternatively, the ECC algorithms 214 may be implemented in the device driver 206.

The processing system 202 may also include an application 208 that may be executed by a processor to provide functionality of the electronic device 200. For example, the application 208 may access the device driver 206 with a request for a page of data or a set of pages from the memory device 210. In one example, the application 208 requests user accessible data, such as compressed music files. As a result, the device driver 206 may retrieve a page from the memory device 210 at an address indicated by the application 208 and may perform error detection and correction on the page as a whole using that error correction code (ECC) associated with the page. The page ECC is stored in the pages metadata or overhead area.

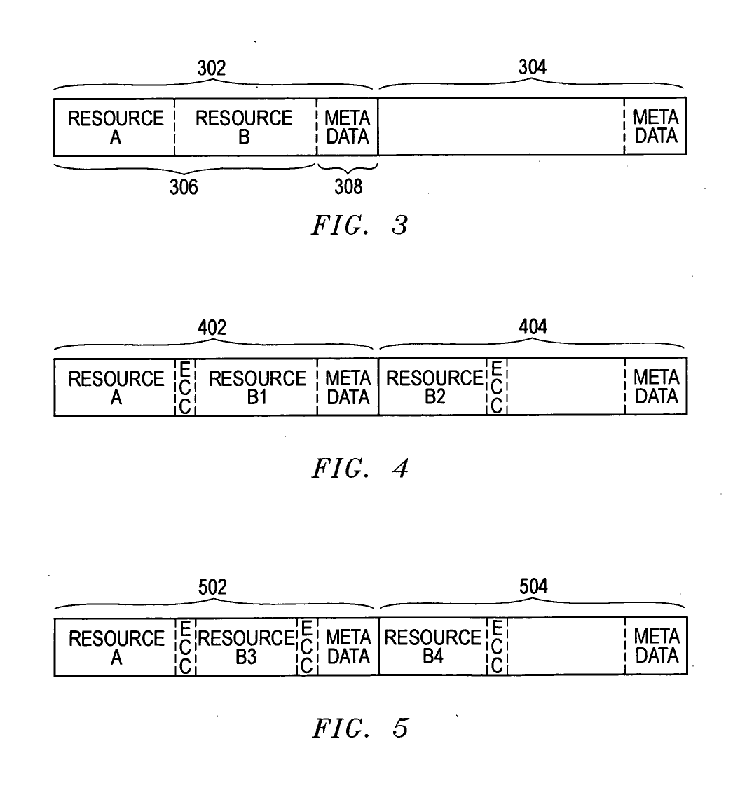

Typically, system resources are stored on the memory device 210 in a system resource image. Often, the system resource image is organized into pages, and a table is stored on the memory device 210 to indicate the storage location of particular system resources. FIGS. 3, 4 and 5 include illustrations of exemplary data organizations within a memory device. For example, FIG. 3 illustrates two pages 302 and 304. The page 302 includes a resource A and a resource B within the data area 306. In an exemplary embodiment, the page 302 may have a data area 306 of 512 bytes and a metadata area 308 of 16 bytes. The pages 302 and 304 may include ECCs within their respective metadata areas that are associated with the respective memory pages as a whole.

When error correction codes (ECC) are associated with system resources that are stored within the user data area, the resource image occupies additional space. FIG. 4 includes an illustration of two pages 402 and 404 including a resource A and a resource B. As illustrated, the resource A has an associated error correction code (ECC) stored within the user data area. As a result, fewer bytes are available for storing additional system resources within the data area. In an exemplary 528 byte page, the 512 byte data area may include an additional 9 byte error correction code (ECC) associated with the resource A. As a result, the resource B may not fit entirely within page 402. To associate an error correction code (ECC) with the resource B, the resource B may be divided and portions, such as a resource B1 and a resource B2 stored on different pages (402 and 404). As illustrated, the error correction code (ECC) is stored on the second page 404 and is appended to the resource B2. The error correction code (ECC) associated with the resource B may provide error correction for the entire resource B, including the portions (resource B1 and resource B2). The system may read and combine the resource B1 and the resource B2, using the error correction code (ECC) to detect and correct errors associated with the combined resource B.

FIG. 5 includes another exemplary embodiment in which an error correction code (ECC) is associated with each portion of a resource that is divided between pages. As illustrated in FIG. 5, the resource B is split between two pages 502 and 504. For example, a portion of resource B, resource B3, is stored on page 502 with an associated error correction code (ECC). The error correction code (ECC) is associated with the resource B3 portion of resource B. On a separate page 504, a second portion of the resource B, resource B4, may also be associated with an error correction code (ECC). When accessing the resource B, resource B3 and the associated ECC may be read from memory and error detection and correction may be performed on the resource B3 portion. In addition, the resource B4 portion and the associated error correction code (ECC) may be read from memory page 504 and error detection and correction performed on the portion resource B4. The resource portions B3 and B4 may be combined to form resource B after error detection and correction.

In general, the system resources are provided to the electronic device during manufacture or in response to updates provided from the manufacturer. When developing system resource software to provide functionality to an electronic device, a manufacturer generally prepares a system resource image and stores that image within the memory of the electronic device.

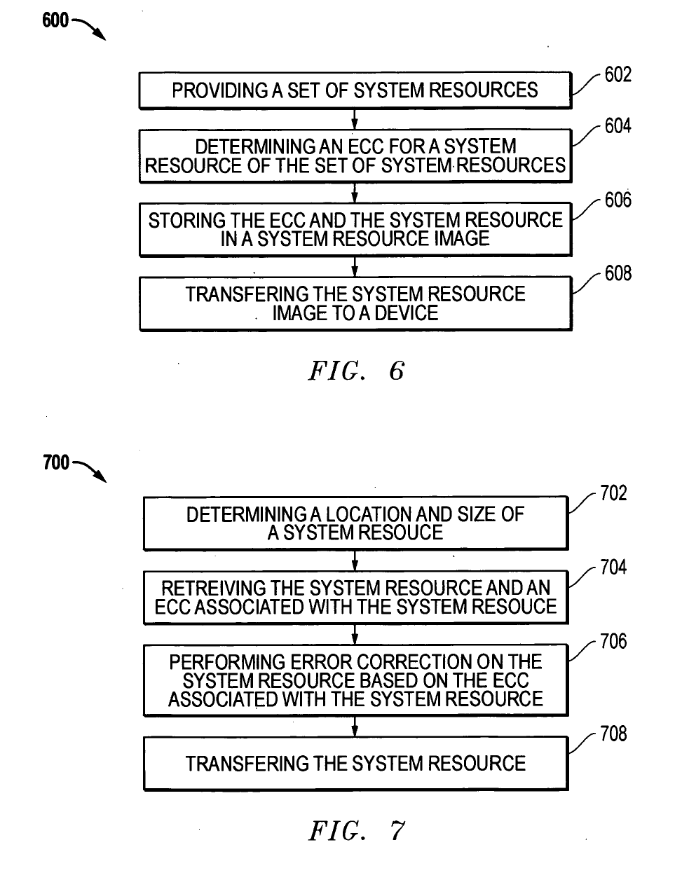

FIG. 6 includes an exemplary method 600 of preparing a system resource. For example, the method may be performed at build time for the system resource. In an exemplary embodiment, a set of system resources is provided, as illustrated at 602. For example, a manufacturer may provide software functions, user interface components, and compression algorithms as a package or set of system resources to provide electronic device functionality. An error correction code (ECC) is determined for a system resource or for each system resource of the set of system resources, as illustrated at 604. For example, each system resource may be used to determine an error correction code (ECC) associated with that system resource. In one exemplary embodiment, the size of a system resource is determined and additional data, such as additional zeros, are appended to the system resource to form data of a select size on which an ECC is formed. For example, an ECC may be formed for a system resource having a size less than 512 bytes by adding additional data, such as binary zeros, to form 512 bytes. The device driver or ECC algorithm may add additional binary data to the system resource to form data having a size that is compatible with the ECC algorithms. In an exemplary embodiment, the ECC detection and correction algorithms are implemented to perform error detection and correction on data of a particular size, such as 512 bytes. The system resource may be less than 512 bytes. As such, additional data, such as binary zeros, may be added to the system resource to form data compatible in size with the ECC algorithm or hardware. In exemplary embodiments, the ECC detection and correction algorithms are implemented in software, hardware or in combinations thereof. In alternative embodiments, particular resource types, such as the software functions, user interface components, or compression algorithms, may be selectively associated with a particular error correction code based on the resource type.

After determining the error correction code for the system resource, the error correction code (ECC) and the system resource are stored in a system resource image, as illustrated at 606. For example, the set of system resources may be stored as a system image. Error corrections codes (ECCs) associated with individual system resources may be appended to the system resource and stored within the system resource image. In a particular embodiment, a system image is organized for storage on particular pages within a memory device, such as a flash memory device. In alternative embodiments, portions of the system image may be stored on memory devices, such as a read-only memory (ROM), for storage close to processing circuitries. Other system resources may be stored on flash memory devices organized in pages.

The system resource image may be transferred to an electronic device, as illustrated at 608. For example, the manufacturer of the electronic device may provide the system image to the electronic device and may provide a table or a set of pointers for locating particular system resources. Such a table may further include the location, offset, and length of a system resource. In addition, the location information and length data may include the error correction code (ECC). In an alternative embodiment, the system image may be provided in an update component downloadable by a user to update system software. When implemented, the update software may upload a system resource image to the electronic device. Users and consumers of electronic devices are generally provided limited access to system resource images and data spaces for storing such images.

Once the electronic device has the system resources and their associated error correction codes, the device may function by accessing the system resources. FIG. 7 includes an illustration of an exemplary method 700 for accessing system resources. In an exemplary embodiment, a resource loader determines a location and size of the system resource, as illustrated at 702. For example, the resource loader may access a set of pointers or a table indicating the sector offset, resource offset, and resource length of a system resource. In one exemplary embodiment, the length of a system resource includes the error correction code associated with the system resource. In an alternative embodiment, the device driver is configured to access an additional set of bytes that include the error correction code associated with the system resource.

Once the location and size of a system resource are determined, the resource loader may direct the device driver to retrieve the system resource and an error correction code (ECC) associated with the system resource, as illustrated at 704. Using the sector offset, resource offset, and resource length, the device driver may access a memory device at the indicated page location and resource offset and retrieve the system resource and the associated error correction code but without retrieving the page as a whole.

Once the system resource and error correction code are retrieved, the system may perform error detection and correction on the system resource based on the ECC associated with the system resource, as illustrated at 706. For example, the device driver or ECC algorithm may add additional binary data to the system resource to form data that is size compatible with the ECC algorithms. In exemplary embodiments, the ECC detection and correction algorithms are implemented to perform error detection and correction on data of a particular size, such as 512 bytes. The error detection and correction are performed on the system resource and appended data using the ECC associated with the system resource.

With an error-free or corrected system resource, the device driver transfers the system resource to the processing system, as illustrated at 708. As a result, the electronic device may function utilizing the system resource.

Particular embodiments of the above described electronic devices and methods, may improve access of system resources and thereby improve the performance of electronic devices. For example, load times of system resources may be reduced by accessing the system resource as opposed to an entire page. Additional advantages may be found in performing error correction on the resource without performing error correction on the page as a whole. For resources having a size that is significantly less than a page size, a reduction in load times and in error correction may significantly improve performance.

The above-disclosed subject matter is to be considered illustrative, and not restrictive, and the appended claims are intended to cover all such modifications, enhancements, and other embodiments, which fall within the true scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A controller comprising:
a memory interface to a memory device;
a device driver configured to access the memory device via the memory interface; and
a resource loader to provide a memory location of a resource to the device driver;
wherein the device driver is configured to access the memory location on the memory device and to retrieve the resource and an error correction code associated with the resource, error correction is performed on the resource based on the associated error correction code.

2. The controller of claim 1, wherein the memory location includes a sector offset, a resource offset, and a resource length.

3. The controller of claim 1, wherein the error correction code is included in a data portion of a memory page.

4. The controller of claim 1, wherein the resource is stored in a memory page within the memory device, the memory device including metadata associated with the memory page, the metadata including a second error correction code.

5. The controller of claim 4, wherein the memory page includes a second resource.

6. The controller of claim 5, wherein the memory page includes a third error correction code associated with the second resource.

7. The controller of claim 1, wherein the memory device includes a flash memory device.

8. A method of providing system resources for an electronic device, the method comprising:
providing a set of system resources;
determining an error correction code for a system resource of the set of system resources; and
storing the error correction code and the system resource in a system resource image.

9. The method of claim 8, further comprising transferring the system resource image to the electronic device.

10. The method of claim 8, wherein the set of system resources form firmware.

11. The method of claim 8, wherein the set of system resources include fonts.

12. The method of claim 8, wherein the set of system resources include software functions for the electronic device.

13. The method of claim 8, wherein determining the error correction code includes determining the error correction code at system resource build time.

14. The method of claim 8, wherein determining the error correction code includes appending data to the system resource and determining the error correction code based on the system resource and the appended data.

15. A method of accessing a system resource, the method comprising:
determining a memory location and a size of the system resource;
retrieving the system resource and an error correction code associated with the system resource from a memory device based on the location and size of the system resource; and
performing error correction on the system resource based on the error correction code.

16. The method of claim 15, wherein the memory includes flash memory.

17. The method of claim 15, wherein determining the memory location and size of the system resource includes accessing a resource table.

18. The method of claim 15, wherein retrieving the system resource and the error correction code includes accessing data stored at the memory location on memory device using a device driver.

19. The method of claim 15, wherein performing error correction on the system resource includes appending data to the system resource and performing error correction on the system resource and the appended data.

20. A memory device comprising:
a memory page including first system resource data and first error correction code data, the first error correction data associated with the first system resource data; and
metadata associated with the memory page, the metadata including second error correction data associated with the memory page.

21. The memory device of claim 20, wherein the memory page further includes a portion of second resource data.

22. The memory device of claim 21, wherein the memory page further includes a third error correction code data associated with the portion of second resource data.

23. The memory device of claim 21, further comprising a second memory page, wherein the second memory page includes third error correction code data associated with the portion of second resource data.

24. The memory device of claim 20, further comprising a third memory page including user data.

25. An electronic device comprising:
a memory device including:
a memory page including first system resource data and first error correction code data, the first error correction data associated with the first system resource data; and
metadata associated with the memory page, the metadata including second error correction data associated with the memory page; and
a controller including:
a device driver configured to access the memory device; and
a resource loader configured to provide a memory location of the first system resource data to the device driver, the device driver configured to access the memory device at the memory location and to retrieve the first system resource data and the first error correction data;
wherein the controller is configured to perform error correction on the first system resource data based on the first error correction data.
